(19) United States
(12) Patent Application Publication
(10) Pub. No.: US 2026/0231379 A1
(43) Pub. Date: Aug. 6, 2026

(54) LIQUID COOLING ARCHITECTURE FOR HIGH-PERFORMANCE DATACENTERS AND OPTIMIZATION METHODS FOR ANY COOLING ARCHITECTURE

(71) Applicant: The Board of Trustees of the University of Illinois, Urbana, IL (US)

(72) Inventors: William P. King, Champaign, IL (US); Nenad Miljkovic, Urbana, IL (US); Ilan Pinkus, Scottsdale, AZ (US); Woo Young Park, Champaign, IL (US); Vishwanath Ganesan, Champaign, IL (US); Omar Zaki, Urbana, IL (US); Xuzhi Du, Savoy, IL (US)

(21) Appl. No.: 19/468,163

(22) Filed: Feb. 3, 2026

Related U.S. Application Data
(60) Provisional application No. 63/752,973, filed on Feb. 3, 2025.

(51) Int. Cl. H05K 7/20; G06F 1/20

(52) U.S. Cl. CPC H05K 7/20836; G06F 1/206; H05K 7/20263; H05K 7/20272; H05K 7/20781

(57) ABSTRACT

A method, system, and computer program product for optimizing a liquid cooling architecture for a datacenter are provided. Operational parameters corresponding to a datacenter and a plurality of server units to be mounted in a rack within the datacenter are received. Groups of one or more server units from among the plurality of server units are determined based on the operational parameters. The server units are caused to be mounted in the rack based on the determined groups. A group of server units from among the determined groups are caused to be connected to a coolant distribution unit, and each server computer in the group of server units is connected to the coolant distribution unit in parallel.

### CROSS-REFERENCE TO RELATED APPLICATIONS

This application claims the benefit of U.S. Provisional Patent Application No. 63/752,973, filed February 3, 2025, with the U.S. Patent and Trademark Office, which is herein incorporated by reference in its entirety.

### STATEMENT REGARDING FEDERALLY SPONSORED RESEARCH OR DEVELOPMENT

This invention was made with government support under DE-AR0001761 awarded by the U.S. Department of Energy. The government has certain rights in the invention.

### TECHNICAL FIELD

This disclosure relates generally to the field of computing, and more particularly to cooling of datacenter IT systems.

### BACKGROUND

A datacenter may be implemented as a building/facility, a dedicated space within a building/facility, or a group of buildings/facilities used to house datacenter information technology (IT) systems and associated components, such as telecommunications and storage systems. Since IT operations are crucial for business continuity, datacenter generally includes redundant or backup components and infrastructure for power supply, data communication connections, environmental controls (e.g., air conditioning, fire suppression), and various security devices. A large datacenter is an industrial-scale operation using as much electricity as a medium town in a much smaller space.

### SUMMARY

Embodiments relate to a method, system, and computer program product for optimizing a liquid cooling architecture for a datacenter. The principles disclosed herein underlying cooling of datacenters apply to other plants and facilities, as well as other industrial and manufacturing settings. While liquid cooling is contemplated by this disclosure, it may be appreciated that other cooling solutions, such as hybrid liquid-air cooling, may be utilized based on the underlying principles disclosed herein.

According to one aspect, a method for optimizing a liquid cooling architecture for a datacenter is provided. The method may include receiving operational parameters corresponding to a datacenter and a plurality of server IT systems to be mounted in a rack within the datacenter. Groups of one or more server IT systems from among the plurality of server IT systems are determined based on the operational parameters. The server IT systems are caused to be mounted in the rack based on the determined groups. A group of server IT systems from among the determined groups are caused to be connected to a cooling distribution unit (CDU), and each server computer in the group of server IT systems is connected to the CDU in parallel.

According to another aspect, a computer system for optimizing a liquid cooling architecture for a datacenter is provided. The computer system may include one or more processors, one or more computer-readable memories, one or more computer-readable tangible storage devices, and program instructions stored on at least one of the one or more storage devices for execution by at least one of the one or more processors via at least one of the one or more memories, whereby the computer system is capable of performing a method. The method may include receiving operational parameters corresponding to a datacenter and a plurality of server IT systems to be mounted in a rack within the datacenter. Groups of one or more server IT systems from among the plurality of server IT systems are determined based on the operational parameters. The server IT systems are caused to be mounted in the rack based on the determined groups. A group of server IT systems from among the determined groups are caused to be connected to a CDU, and each server computer in the group of server IT systems is connected to the CDU in parallel.

According to yet another aspect, a computer program product for optimizing a liquid cooling architecture for a datacenter is provided. The computer program product may include one or more computer-readable storage devices and program instructions stored on at least one of the one or more computer-readable storage devices, the program instructions executable by a processor. The program instructions are executable by a processor for performing a method that may accordingly include receiving operational parameters corresponding to a datacenter and a plurality of server IT systems to be mounted in a rack within the datacenter. Groups of one or more server IT systems from among the plurality of server IT systems are determined based on the operational parameters. The server IT systems are caused to be mounted in the rack based on the determined groups. A group of server IT systems from among the determined groups are caused to be connected to a CDU, and each server computer in the group of server IT systems is connected to the CDU in parallel.

According to another aspect, a liquid cooling architecture for a datacenter is provided. The liquid cooling architecture may include a rack; one or more groups of server IT systems mounted within the rack having a size of one rack unit (1U), two rack units (2U), three rack units (3U), or more; a primary cooling loop with a cooling unit or heat exchanger to dissipate the heat to a cooling medium, one or more first pipes or tubes, and one or more first pumps; a secondary cooling loop for each of the one or more groups of server units, each secondary cooling loops including one or more coolers in contact with the one or more components of the server units, one or multiple CDUs mounted to a rear side of the rack and connected in series or parallel with each server computers in the group. The CDU or CDUs comprise of one or more second pipes or tubes, and one or more second pumps mounted to the rear side of the rack; and one or more heat exchangers mounted to the rear side of the rack (within the CDUs) and operatively coupled to the primary cooling loop and the secondary cooling loop.

### BRIEF DESCRIPTION OF THE DRAWINGS

These and other objects, features and advantages will become apparent from the following detailed description of illustrative embodiments, which is to be read in connection with the accompanying drawings. The various features of the drawings are not to scale as the illustrations are for clarity in facilitating the understanding of one skilled in the art in conjunction with the detailed description. In the drawings:

FIG. 1 illustrates a networked computer environment according to at least one embodiment;

FIG. 2 is a block diagram of an optimized liquid cooling architecture for a datacenter, according to at least one embodiment;

FIG. 3A is a schematic diagram of a datacenter dynamic simulation model, according to at least one embodiment;

FIG. 3B is a schematic diagram of an in-rack dynamic simulation model, according to at least one embodiment;

FIG. 4 is an operational flowchart illustrating the steps carried out by a program that optimizes a liquid cooling architecture for a datacenter, according to at least one embodiment;

FIG. 5 is an operational flowchart illustrating steps for determining groups of one or more server units from among the plurality of server units based on the operational parameters according to one or more embodiments of FIG. 4; and

FIG. 6 is a block diagram of internal and external components of IT systems and servers depicted in FIG. 1 according to at least one embodiment.

### DETAILED DESCRIPTION

Detailed embodiments of the claimed structures and methods are disclosed herein; however, it can be understood that the disclosed embodiments are merely illustrative of the claimed structures and methods that may be embodied in various forms. Those structures and methods may, however, be embodied in many different forms and should not be construed as limited to the exemplary embodiments set forth herein. Rather, these exemplary embodiments are provided so that this disclosure will be thorough and complete and will fully convey the scope to those skilled in the art. In the description below, details of well-known features and techniques may be omitted to avoid unnecessarily obscuring the presented embodiments.

Embodiments relate generally to the field of computing, and more particularly to cooling of datacenter IT systems. The following described exemplary embodiments provide a system, method and computer program to, among other things, optimize the architecture of datacenter cooling solutions. Therefore, some embodiments have the capacity to improve the field of computing by improving the functioning of IT systems through improved cooling of computer components.

As previously described, a datacenter may be implemented as a building/facility, a dedicated space within a building/facility, or a group of buildings/facilities used to house computer systems and associated components, such as telecommunications, artificial intelligence (AI) computing, machine learning (ML) computing, networking, storage systems, and any other data service. Since information technology (IT) operations are crucial for business continuity, it generally includes redundant or backup components and infrastructure for power supply, data communication connections, environmental controls (e.g., air conditioning, fire suppression), and various security devices. The sustainable performance of a datacenter is significant to achieve these objectives, and liquid cooling may become essential to avoid the unexpected performance limit. A large datacenter is an industrial-scale operation using as much electricity as a medium town in a much smaller space and may thus use highly efficient, high-throughput cooling solutions to maintain normal or optimal operating conditions.

The evolution of generative AI is driving a significant revolution in the datacenter industry with transformations in computing infrastructure, power management, and cooling technologies. However, this revolution has substantially increased the server rack power density for carrying out high-performance computing (HPC). While the traditional legacy datacenters tend to generate around 3-20 kW per rack (in particular, around 4-5 kW per rack), the current HPC datacenters may generate around 100 kW per rack of power density. It may be advantageous, therefore, to employ improved cooling technologies to support high power densities in HPC datacenters. One such cooling technology may start with a system-level dynamic analysis of an HPC datacenter. This may allow for optimal cooling system design and determination of an optimal range of parameters, such as cooling liquid flow rate and liquid temperature, to provide specific liquid cooling solutions tailored to datacenters with dynamic thermal loads and ambient conditions.

The cooling system disclosed herein offers optimized liquid cooling solutions specifically tailored for datacenters with dynamic thermal loads and varying ambient conditions. Utilizing advanced simulation tools, a comprehensive dynamic model integrates detailed component specifications and real-world physical phenomena. The system supports modular and scalable design, ensuring flexible implementation across different datacenter configurations. It demonstrates significant improvements in thermal efficiency and energy consumption through innovative control mechanisms and real-time monitoring. The versatile application of the method disclosed herein extends beyond datacenters to other applications with precise thermal management. The robust framework ensures reliability and accuracy, while the user-friendly interface enhances accessibility for engineers and researchers. The system's ability to maintain optimal performance under varying conditions and its support for innovative development validates its effectiveness and advances the field of dynamic cooling solutions.

Aspects are described herein with reference to flowchart illustrations and/or block diagrams of methods, apparatus (systems), and computer readable media according to the various embodiments. It will be understood that each block of the flowchart illustrations and/or block diagrams, and combinations of blocks in the flowchart illustrations and/or block diagrams, can be implemented by computer readable program instructions.

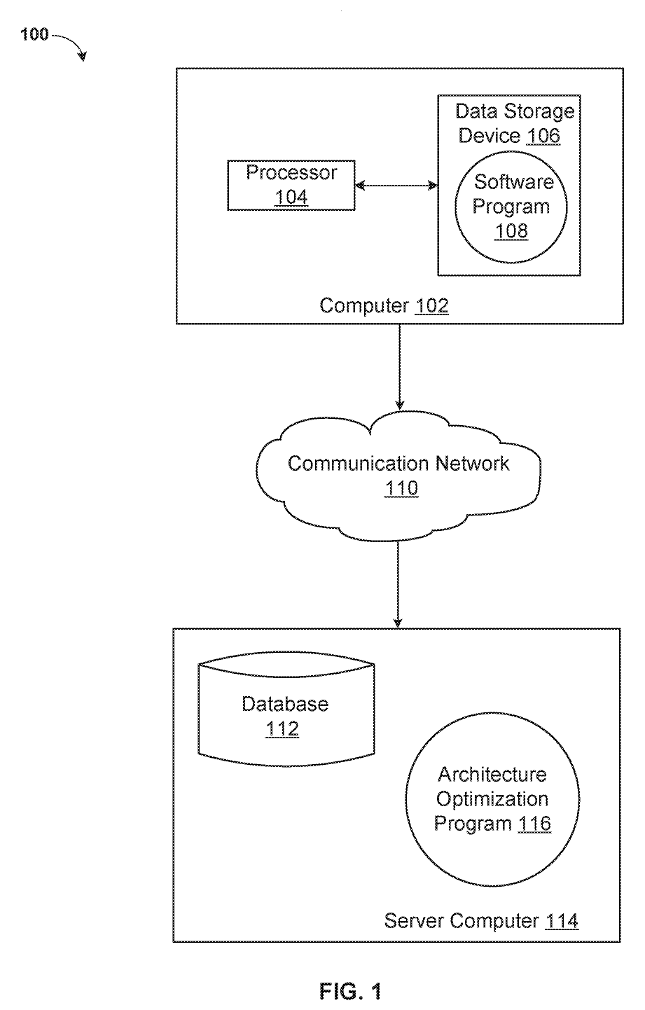

The following described exemplary embodiments provide a system, method and computer program that optimizes a liquid cooling architecture for a datacenter. Referring now to FIG. 1, a functional block diagram of a networked computer environment illustrating a cooling optimization system 100 (hereinafter “system”) for optimizes a liquid cooling architecture for a datacenter. It should be appreciated that FIG. 1 provides only an illustration of one implementation and does not imply any limitations with regard to the environments in which different embodiments may be implemented. Many modifications to the depicted environments may be made based on design and implementation details.

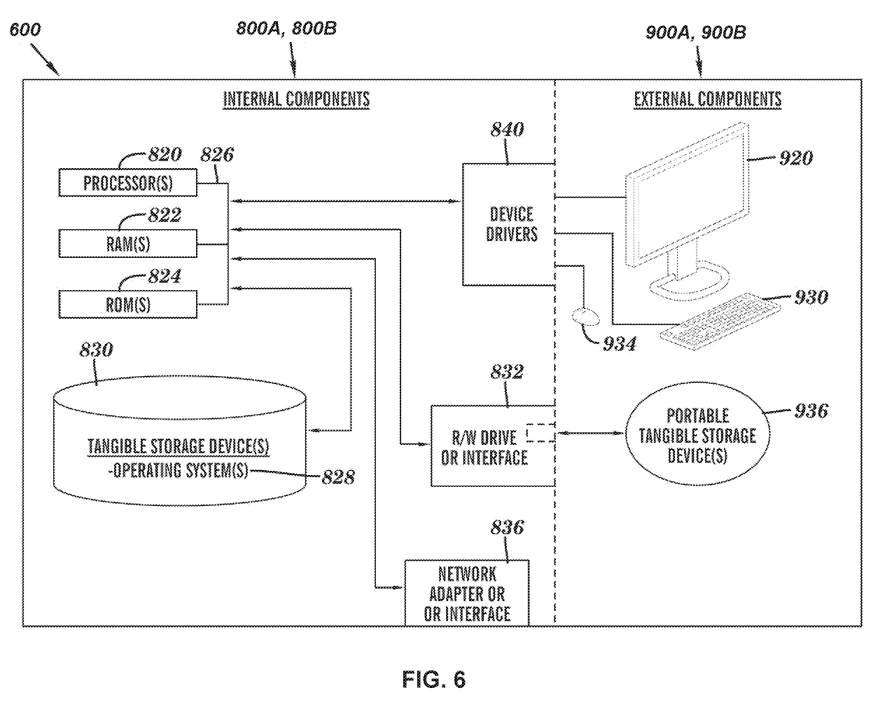

The system 100 may include a computer 102 and a server computer 114. The computer 102 may communicate with the server computer 114 via a communication network 110 (hereinafter “network”). The computer 102 may include a processor 104 and a software program 108 that is stored on a data storage device 106 and is enabled to interface with a user and communicate with the server computer 114. As will be discussed below with reference to FIG. 6 the computer 102 may include internal components 800A and external components 900A, respectively, and the server computer 114 may include internal components 800B and external components 900B, respectively. The computer 102 may be, for example, a mobile device, a telephone, a personal digital assistant, a netbook, a laptop computer, a tablet computer, a desktop computer, or any type of computing devices capable of running a program, accessing a network, and accessing a database.

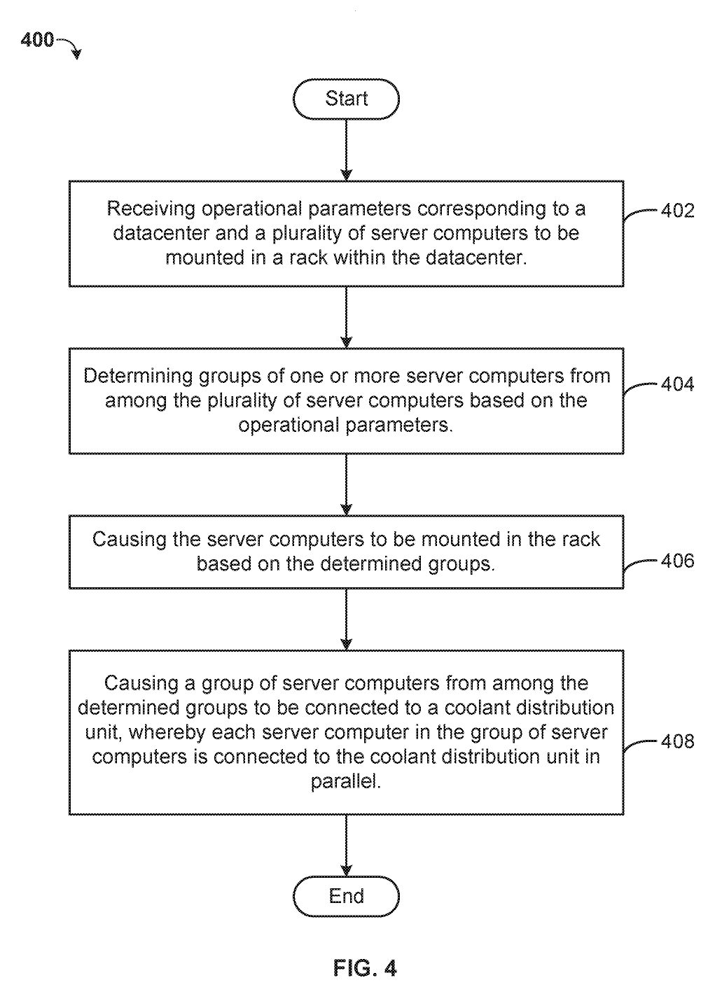

The server computer 114, which may be used for optimizing a liquid cooling architecture for a datacenter is enabled to run an Architecture Optimization Program 116 (hereinafter “program”) that may interact with a database 112. The program 116 may, among other things, iteratively simulate candidate datacenter cooling architectures based on operational parameters of components of the datacenter cooling architecture, transient heat load data, weather data, and/or datacenter ambient temperature data. The Architecture Optimization Program method is explained in more detail below with respect to FIG. 4. In one embodiment, the computer 102 may operate as an input device including a user interface while the program 116 may run primarily on server computer 114. In an alternative embodiment, the program 116 may run primarily on one or more computers 102 while the server computer 114 may be used for processing and storage of data used by the program 116. It should be noted that the program 116 may be a standalone program or may be integrated into a larger architecture optimization program.

It should be noted, however, that processing for the program 116 may, in some instances be shared amongst the computers 102 and the server computers 114 in any ratio, including solely on one computer 102 or one server computer 114. In another embodiment, the program 116 may operate on more than one computer, server computer, or some combination of computers and server computers, for example, a plurality of computers 102 communicating across the network 110 with a single server computer 114. In another embodiment, for example, the program 116 may operate on a plurality of server computers 114 communicating across the network 110 with a plurality of client computers. Alternatively, the program may operate on a network server communicating across the network with a server and a plurality of client computers.

The network 110 may include wired connections, wireless connections, fiber optic connections, or some combination thereof. In general, network 110 can be any combination of connections and protocols that will support communications between the computer 102 and the server computer 114. The network 110 may include various types of networks, such as, for example, a local area network (LAN), a wide area network (WAN) such as the Internet, a telecommunication network such as the Public Switched Telephone Network (PSTN), a wireless network, a public switched network, a satellite network, a cellular network (e.g., a fifth generation (5G) network, a long-term evolution (LTE) network, a third generation (3G) network, a code division multiple access (CDMA) network, etc.), a public land mobile network (PLMN), a metropolitan area network (MAN), a private network, an ad hoc network, an intranet, a fiber optic-based network, or the like, and/or a combination of these or other types of networks. The number and arrangement of devices and networks shown in FIG. 1 are provided as an example. In practice, there may be additional devices and/or networks, fewer devices and/or networks, different devices and/or networks, or differently arranged devices and/or networks than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of system 100 may perform one or more functions described as being performed by another set of devices of system 100.

The server systems above may constitute part of or all of a datacenter. A datacenter may include a plurality of server systems above and other additional components. The server systems and the other additional components of the datacenter may be organized into racks. Each rack may include a plurality of data processing units (referred to as units for simplicity). For example, a rack in the datacenter may be configured to accommodate a maximum of 42 or other number of units. The rack may be configured to provide a plurality of slots for inserting the units so the units are connected to various power, data, and cooling connections. Each unit may be individually inserted into any slot in the rack. Each unit may include electric, computing, storage, cooling (CDU), and other components to achieve one or more functions of the datacenter.

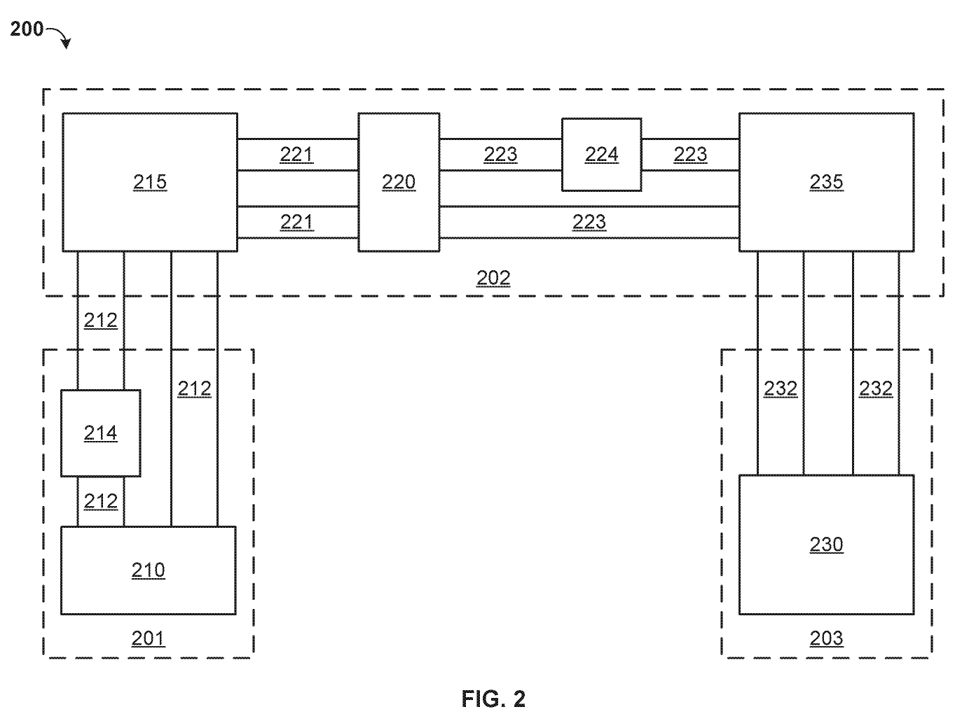

Referring now to FIG. 2, a block diagram of an optimized liquid cooling system 200 for a datacenter configured in racks of data processing units is depicted, according to one or more embodiments. The optimized liquid cooling system 200 may include, among other things, a primary cooling loop 201, one or more coolant distribution units (CDUs) 202, and a secondary cooling loop 203. The primary cooling loop 201 may include a primary-side cooling unit 210, one or more primary connections 212, and one or more pumps 214. The secondary cooling loop 203 may include, among other things, one or more secondary-side cooling units 230 and one or more secondary connections 232. The one or more coolant distribution units may include, among other things, one or more heat exchangers 220, one or more internal primary-side connections 221, one or more internal secondary-side connections 223, one or more pumps 224, a primary-side manifold 215, and a secondary-side manifold 235. The one or more heat exchangers 220, the one or more internal secondary-side connections 223, the one or more pumps 224, and the one or more internal secondary-side connections 223, which make up part of the one or more CDUs 202, may thermally and fluidically connect the primary and secondary side. The secondary-side cooling units 230 may be connected to IT and server equipment within the unit to provide thermal management to the electrical and mechanical components.

The primary cooling loop 201 may be a facility cooling loop that may, for example, run outdoors to primary-side cooling unit 210, such as a dry cooler, wet cooler, or adiabatic cooler. The secondary cooling loop 203 may be a rack-level cooling loop that cools the rack-mounted components of the datacenter. While only one rack is depicted in the secondary cooling loop 203, it may be appreciated that any number of racks may be connected to a primary cooling loop 201. In a rack, any number of server units may be cooled by the secondary cooling loop 203, or that any server units from among multiple server units may be cooled by any one or more secondary cooling loops 203 from among multiple secondary cooling loops 203, or that any number of independent secondary cooling loops 203 may be connected to the CDU 202. Any number of independent CDUs 202 may be used for each rack. A single CDU 202 may be used to service multiple racks. Any CDUs 202 from among multiple CDUs 202 may be connected to the primary cooling loop 201.

The primary-side cooling unit 210 may be located outdoors in relation to the datacenter such that heat from the secondary cooling loop 203 may be moved outside of the datacenter and not contribute to raising the indoor ambient temperature. The primary-side cooling unit 210 may be, for example, a dry cooler with an approximate size of two meter by ten meters by three meter that may manage an approximately 2.9 MW heat load. This dry cooler unit may be connected to a multiple rack. The space efficiency of the primary-side cooling unit 210 may increase with additional racks since the primary-side cooling units 210 may be vertically stacked. The primary-side cooling unit 210 may also be, for example, a wet cooler or adiabatic cooler.

The one or more CDUs 202 may be located/distributed within the racks of server IT systems within the datacenter. The CDUs 202 may be rack-mounted units that may have flow rates between 0.1 and 54 liters per minute allowing active control of the pump to achieve consistent junction temperature of computing units based on dynamic simulation results. Although the CDUs 202 may be substantially any size (e.g., 1 rack unit (1U) to 42 rack units (42U)), a balance between cooling capacity and modularity may be achieved at a height of three rack units (3U). For example, for a single standard 42U rack, fourteen CDUs 202 (i.e., one CDU 202 for every 3U) may be used to connect all the in-rack flow loops (i.e., the secondary cooling loop 203) to the facility-side loop (i.e., the primary cooling loop 201). A single CDU 202 may connect three server units in a parallel flow configuration. A single CDU 202 may connect one 3U server unit in a parallel flow configuration. Each computing component, including graphics processing units (GPUs), central processing units (CPUs), memories, solid-state drives (SSDs), and power supply unites (PSUs), has a direct integration of thermal interface material (TIM) and cooler. Within each 1U server computer, major heat source IT components, such as GPUs, CPUs, and memories, are connected in parallel, while other components are connected in series. This in-rack flow loop is connected to the 3U CDU 202, which is then connected to the facility-side loop. Since each in-rack flow loop is connected in parallel, this results in a less-sensitive power consumption in response to the increased pressure drop of the coolers.

The design of the CDUs 202 may help maximize the server rack power density and at the same time minimizes the system cooling power consumption by efficiently delivering heat from IT components to the outdoors. The 3U-sized, modular, liquid-to-liquid CDU 202, positioned on the backside of a server rack, distributes coolant in a modular fashion using the rack manifold into the server units (of a 42U rack server). Because the CDU 202 is modular and may not require additional installation space, the power density achieved may be significantly greater than other architectures and a lower TUE may be achieved. Utilizing both parallel and series flow loop connections for coolers developed using cooler design optimization for cooling ultra-high power density chips and coolers for cooling auxiliary IT components within each server unit, the liquid cooling system 200 achieves both uniform cooling performance and lower pressure drop. The coolers may be conventional metallic coolers made from copper (Cu) or aluminum (Al), or a bimetallic microstructured cooler with a copper-tungsten (CuW) base plate bonded to a Cu top layer, as described in “MICROCOOLER FOR DIRECT-TO-CHIP COOLING AND METHODS OF MANUFACTURING A MICROCOOLER,” which is herein incorporated by reference in its entirety. It may be appreciated that the coolers may be of substantially architecture and/or construction. This self-contained in-row CDU 202 is connected to the existing facility cooling loop (i.e., utilizing facility water) which then rejects heat to the outdoor air via a dry cooler that facilitates the transfer of heat out of the CDU to the outdoors.

The heat exchanger 220 may be a brazed plate heat exchanger (BPHX) to ensure even heat transfer from the secondary cooling loop 203 to the primary cooling loop 201. The heat exchanger 220 may, for example, measure approximately two-hundred by eighty by fifty millimeters and can handle a heat load of up to approximately 15 kW, with a pressure drop of approximately 13 kPa on the secondary side and 12 kPa on the primary side.

The one or more primary connections 212, the one or more internal primary-side connections 221, the one or more internal secondary-side connections 223, and the one or more secondary connections 232 may be pipes, tubes, or the like that may be used to carry coolant from hot components, such as the rack-mounted servers, via the secondary-side cooling unit 230 to the heat exchanger 220 and from the heat exchanger 220 to the primary-side cooling unit 210 outdoors. For example, the one or more primary connections 212, the one or more internal primary-side connections 221, the one or more internal secondary-side connections 223, and the one or more secondary connections 232 may carry hot water near 60°C or more for its potential for heat reuse in surrounding facilities. In this scenario, the temperature difference between the coolant and the indoor ambient becomes significant. Therefore, the amount of heat loss must be considered to achieve better energy delivery from the datacenter to the outdoors. Additionally, heat loss causes an increase in indoor temperature, necessitating an extra cooling system for the indoor ambient temperature of the datacenter. The one or more primary connections 212, the one or more internal primary-side connections 221, the one or more internal secondary-side connections 223, and the one or more secondary connections 232 may use conventionally manufactured (e.g., casting, milling, forging, powder sintering, extruding, machining, etc.) or 3D-printed T-connectors, 90-degree connectors, quick-disconnect fittings, and manifolds, made of a low thermal conductivity material in order to reduce heat loss. The use of quick-disconnect fittings may facilitate easier maintenance and replacement of components without draining the system while preventing leakage. The primary-side manifold 215 may couple the one or more primary connections 212 with the one or more internal primary-side connections 221. The secondary-side manifold 235 may couple the one or more internal secondary-side connections 223 and the one or more secondary connections 232.

The one or more pumps 214, 224 may be used to move coolant through the primary cooling loop 201 and the secondary cooling loop 203, respectively. Secondary redundant pumps may be used to provide redundancy in case of failure of a single pump. The pumps 224 may be, for example, pumps that can position on the backside of the rack, not requiring additional space can manage liquid flow up to approximately 30 liters per minute per server unit and liquid temperatures up to 93^{o}C. Given that the server size, for example, is approximately 550 by 800 by 50 millimeters or smaller, or even larger, there may be sufficient space to place both the pump and BPHX on the backside of a standard 42U rack. The use of rack manifolds with fewer flow distribution channels, due to the modular architecture of the CDUs 202, helps in increasing pump efficiency. Since the CDU 202 is designed to operate at even high coolant temperatures, materials like low thermal conductivity connectors and silicone-foam insulation serve to minimize heat loss and prevent server room heating. Thus, both the geometry and the material selection may be considered for enhancing pump efficiency. The liquid cooling system 200 may use active control strategies for pumps and fans to dynamically adjust and maintain target junction temperatures and optimize power consumption

One or more sensors may collect input dynamic physical signals, such as transient heat load and weather data, for iterating the construction of real-world physical models, including each component within the CDU architecture and server unit. The sensors may collect thermal and hydraulic component data that may allow for reasonable and reliable results to be obtained with basic boundary conditions used for constructing complex real-world systems.

Thus, with an objective to minimize the total power usage effectiveness (TUE), the optimized liquid cooling system 200 leverages the cooler geometry for pressure drop calculations and determines the maximum allowable cooling power based on TUE, and, thus, the maximum allowable pumping power for the coolers, which is, in turn, may be used for cooler design optimization for designing the optimal cooler geometry. Hence, for a 3U modular liquid cooling architecture, the cooler design optimization algorithm is coupled with the CDU design optimization and sizing, as well as the primary side component such as the dry cooler optimization and sizing to iterate over both system-level and cooler-level design and operational variables.

This optimization approach helps identify the best fluid circulatory network for a modular CDU architecture and cooler design that gives the best overall performance quantified by both cooler-level metric (e.g., minimum case-to-coolant thermal resistance, maintenance of a minimum cooler feature size, cooler cost) and system-level metric (e.g., minimum TUE). This optimized design solution is specific to a fixed IT thermal load and ambient conditions. The model that utilizes the information from the optimization analysis for cooler and CDU design and integrates such information and applies to a datacenter at the system level to dynamically predict the system-level performance, taking into consideration the dynamic nature of thermal loads and ambient conditions.

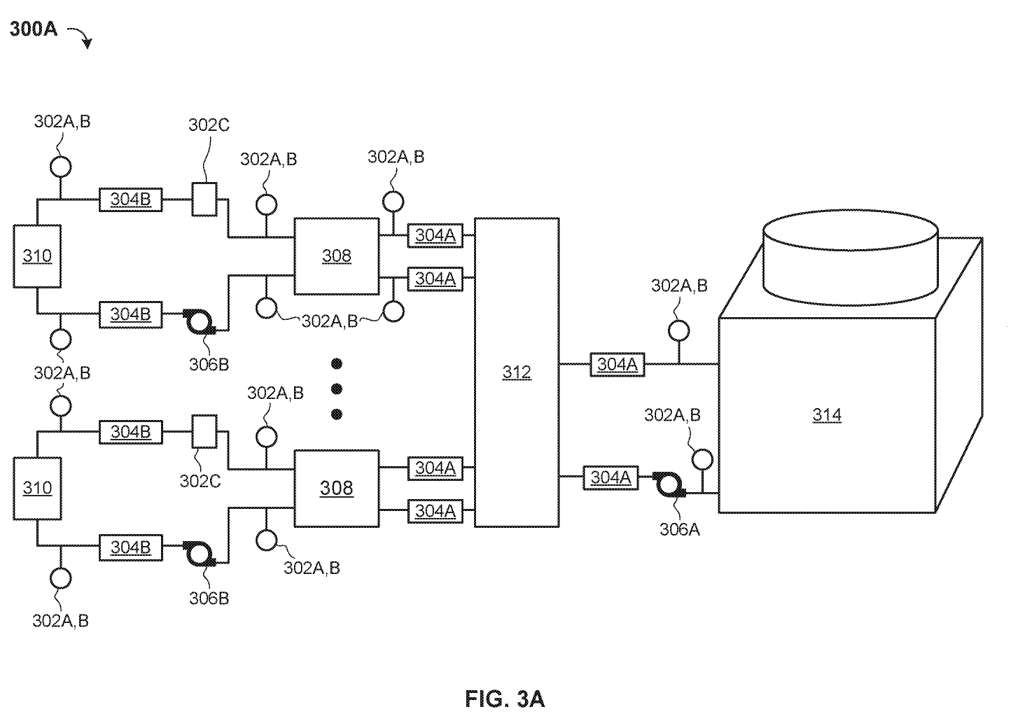

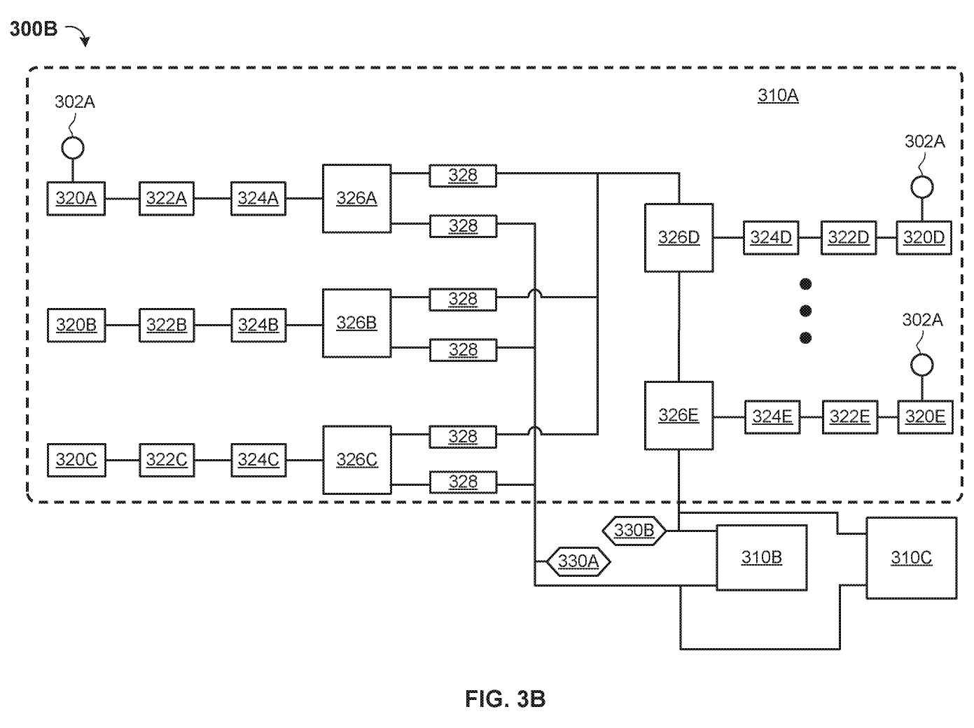

Referring now to FIG. 3A, a schematic diagram of a datacenter dynamic simulation model 300A is depicted according to one or more embodiments. The datacenter dynamic simulation model 300A shows the fundamental structure of a single rack dynamic model, which includes multiple sensors 302A,B,C for respectively measuring liquid temperature, pressure, and flow rate at various points within the loop. Detailed specifications for pipes 304A on the primary loop, pipes 304B on the secondary loop, pumps 306A on the primary loop, pumps 306B on the secondary loop and one or more heat exchangers 308 between the primary and secondary loops may be provided for the datacenter dynamic simulation model 300A to model the datacenter cooling architecture. The secondary loop may represent indoor components and parameters, such as the server units 310, coolers, other information technology (IT) components, and ambient temperature. The primary loop may include outdoor components and parameters, such as manifold 312, outdoor cooling units (dry coolers 314, wet coolers, adiabatic coolers, liquid coupled heat exchangers) and weather conditions.

Referring now to FIG. 3B, a schematic diagram of an in-rack dynamic simulation model 300B is depicted according to one or more embodiments. Since a 3U modular CDU may be used for the server unit 310 (FIG. 3A), the in-rack dynamic simulation model 300B may be applicable for three 1U rack-mounted servers 310A,B,C or a single 3U server 310. For each server unit 310 or 310A,B,C, there is a set of coolers 324A,B,C transmitting the transient thermal loads 322A,B,C from IT components 320A,B,C (e.g., CPU, GPU, etc.) to the cooler blocks. After this load is transmitted, the coolers 326A,B,C may be integrated into the model, including thermal interfacial material 324A,B,C. Tube properties may be assigned to internal pipes 328, the fluid inlet 330A from the secondary loop of the cooling architecture, and fluit outlet 330B to the secondary loop of the cooling architecure. These three integrations (i.e., 320A,B,C) representing multi-chip modules (MCMs) are connected in parallel. Other major components 320D,E, such as memory (e.g., dual in-line memory modules; DIMMs), power supply units (PSUs), and solid-state drives (SSDs) are then connected in series and may transmit transient thermal loads 322D,E to coolers 320D,E through thermal interface material 324D,E. Temperature sensors 302A may also be included.

The simulation models 300A of FIG. 3A and 300B of FIG. 3B may include multiple measuring points for temperature, pressure, and flow rate of each component, enabling real-time monitoring and dynamic adjustments to maintain optimal cooling performance. The simulation framework may offer an accessible interface and a versatile coding environment for engineers and researchers to model and simulate datacenter cooling systems while providing system-level analysis that integrates both thermal and hydraulic components, offering a complete view of cooling system performance under variable conditions.

Block diagrams may be used in the dynamic simulations to represent mathematical operations and engineering components organized by physical domains: electrical, mechanical rotational, and translational, isothermal liquid, gas, etc. Within each domain, the blocks are categorized into elements, sources, and sensors. Physical modeling of multidomain systems is accomplished by arranging and connecting well-defined calculating blocks, including components such as heat flow rate source, thermal mass, heat resistance, pipe, pump, heat exchanger, fan, sensors of temperature, pressure and flow rate, etc. These blocks allow simulation of the actual datacenter architecture. Coupled with dynamic boundary conditions such as heat load and ambient weather data, including temperature and humidity, input through signal blocks, system-level simulations of the dynamic behavior of a datacenter cooling system can be performed, ensuring an accurate representation of real-world physical phenomena

Referring now to FIG. 4, an operational flowchart illustrating the steps of a method 400 carried out by a program that optimizes a liquid cooling architecture for a datacenter is depicted. FIG. 4 may be explained with the aid of the embodiments of FIGS. 1-3B.

At 402, the method 400 may include receiving operational parameters corresponding to a datacenter and a plurality of server units to be mounted in a rack within the datacenter. The operational parameters include transient heat load information for the server units, cooling solution connectivity configuration information for the server units, weather or climate data corresponding to a location of the datacenter, and ambient temperature within the datacenter. In operation, the architecture optimization program 116 (FIG. 1) on the server computer 114 (FIG. 1) may retrieve operational parameter data from the database 112 (FIG. 1) on the server computer 114 or may receive the operational parameter data from the software program 108 (FIG. 1) on the computer 102 (FIG. 1) via the communication network 110 (FIG. 1).

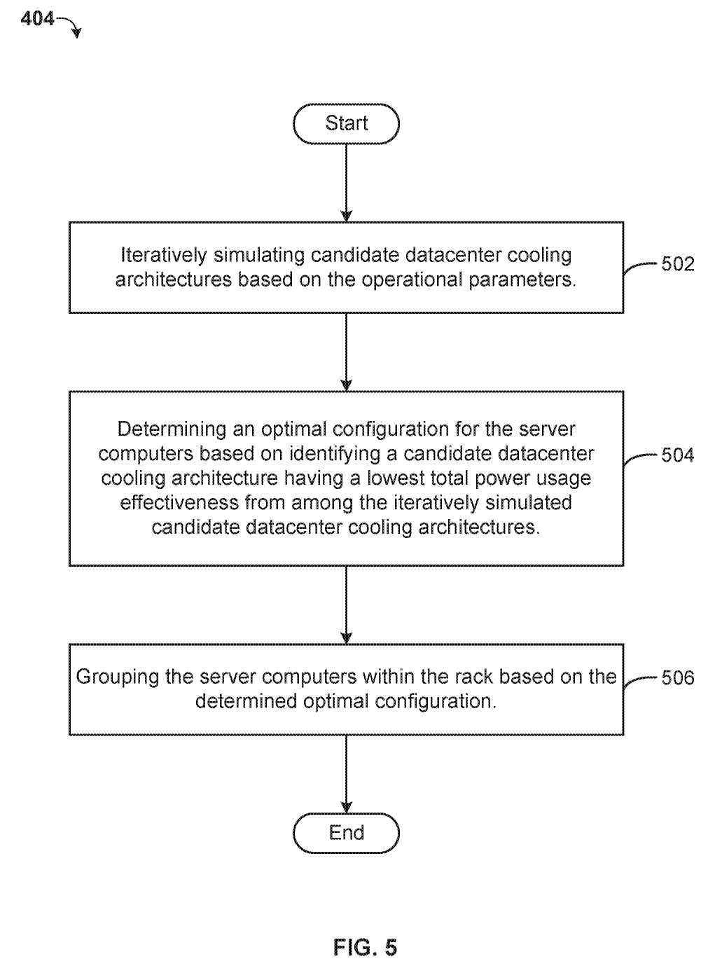

At 404, the method 400 may include determining groups of one or more server units from among the plurality of server units based on the operational parameters. 404 will be explained in more depth with regard to FIG. 5.

At 406, the method 400 may include causing the server units to be mounted in the rack based on the determined groups. Each group of server units includes servers mounted within the rack having a size of one rack unit (1U), two rack units (2U), three rack units (3U), or more. In operation, the Architecture Optimization Program 116 (FIG. 1) may cause the server units #1-U, #2-U, and #3-U (FIG. 3B) to be mounted in a rack.

At 408, the method 400 may include causing a group of server units from among the determined groups to be connected to a coolant distribution unit, wherein each server computer in the group of server units is connected to the coolant distribution unit in parallel. The coolant distribution unit has a height of three rack units (3U) and is caused to be mounted to a rear side of the rack. In operation, the Architecture Optimization Program 116 (FIG. 1) may cause the server units #1-U, #2-U, and #3-U (FIG. 3B) to be coupled in parallel to a single coolant distribution unit (CDU) 202 (FIG. 2) in the rack.

Referring now to FIG. 5, an operational flowchart illustrating a method 404 for determining groups of one or more server units from among the plurality of server units based on the operational parameters according to one or more exemplary embodiments of FIG. 4 is depicted. FIG. 4 may be explained with the aid of the embodiments of FIGS. 1-4.

At 502, the method 404 may include iteratively simulating candidate datacenter cooling architectures based on the operational parameters. A datacenter cooling architecture corresponding to the candidate datacenter cooling architectures includes a primary cooling loop with a cooling unit, one or more first pipes or tubes, and one or more first pumps; a secondary cooling loop with a coolers, the coolant distribution unit, one or more second pipes or tubes, and one or more second pumps; and one or more heat exchangers coupled to the primary cooling loop and the secondary cooling loop. In operation, the datacenter cooling architecture includes a primary cooling loop 201 (FIG. 2) with a primary-side cooling unit 210 (FIG. 2), one or more primary connections 212 (FIG. 2), and one or more pumps 214 (FIG. 2); a coolant distribution unit (CDU) 202 (FIG. 2) with one or more heat exchangers 220 (FIG. 2), one or more pumps 224 (FIG. 2), one or more internal primary-side connections 221 (FIG. 2), one or more internal secondary-side connections 223 (FIG. 2), a primary-side manifold 215, and a secondary-side manifold 235; and a secondary cooling loop 203 (FIG. 2) with a secondary-side cooling unit 230 and one or more secondary connections 232 (FIG. 2). The primary and secondary cooling loops are connected via one or more CDUs 202 (FIG. 2). The Architecture Optimization Program 116 (FIG. 1) may iterate through configurations of server units #1-U, #2-U, and #3-U (FIG. 3B) within the datacenter cooling architecture based on transient heat load information for the 1U servers #1-U, #2-U, and #3-U; cooling solution connectivity configuration information for the 1U servers #1-U, #2-U, and #3-U; weather or climate data for the datacenter; and ambient temperature within the datacenter.

At 504, the method 404 may include determining an optimal configuration for the server IT systems based on identifying a candidate datacenter cooling architecture having a lowest total power usage effectiveness from among the iteratively simulated candidate datacenter cooling architectures. Determining the optimal configuration for the server IT systems may further include iteratively determining a shape of the coolers based on minimizing the total power usage effectiveness or maximizing performance (minimizing thermal resistance). Determining the optimal configuration for the server IT systems may further include iteratively determining the fluidic connection architecture within the server (e.g., from CPU to memory, etc.) as well as the connection sizing from component to component based on minimizing the total power usage effectiveness or maximizing performance (minimizing thermal resistance). In operation, the Architecture Optimization Program 116 (FIG. 1) may determine the optimal configuration is for the server units #1-U, #2-U, and #3-U (FIG. 3B) or more to be included within the secondary cooling loop 203 (FIG. 2).

At 506, the method 404 may include grouping the server units within the rack based on the determined optimal configuration. As previously described, the groups each include one or more server units that are to be connected in parallel with a coolant distribution unit. In operation, the Architecture Optimization Program 116 (FIG. 1) may group the 1U servers #1-U, #2-U, and #3-U (FIG. 3B) together for coupling to the CDU 202 (FIG. 2).

It may be appreciated that FIGS. 4 and 5 provides only an illustration of one implementation and do not imply any limitations with regard to how different embodiments may be implemented. Many modifications to the depicted environments may be made based on design and implementation requirements.

The present disclosure may include a methodology for designing a topology optimized cooler that starts with 2D topology optimized design and then creates a 3D design that is an extruded form of the 2D design. The 2D design uses multi-objective optimization algorithms to balance heat transfer efficiency, pressure drop minimization, and manufacturing constraints. The present disclosure may include a 3D topology optimized manifold plenum region that evenly distributes fluid and minimize pressure drop while adhering to additive manufacturing design constraints. The present disclosure may include a topology optimization methodology for designing high-performing plenums which minimizes fluid nonuniformity or minimizes pressure drop.

The present disclosure may include 3D topology optimized pin structures that enhance heat transfer by promoting flow circulation and restarting thermal boundary layer development and can be patterned across the cooler surface. The present disclosure may include a methodology for 3D topology optimization of an entire cold plate including multiple coupled design domains with different optimization and flow-related objective functions. The objective functions may apply different weights to, for example, temperature minimization or the pressure drop minimization to favor one over the other as needed. The present disclosure may include an array of wire EDM machined diamond pins with optimal geometric parameters to balance thermal resistance, pressure drop, and manufacturing constraints. The present disclosure may include an array of conventionally machined (e.g., casting, milling, forging, powder sintering, extruding, machining, etc.) fins with optimal geometric parameters based on thermal resistance, pressure drop, and manufacturing constraints. The present disclosure may include an array of skived fins with optimal geometric parameters based on thermal resistance, pressure drop, and manufacturing constraints.

The present disclosure may include a bimetallic cold plate that uses bonded layers of two or more materials to limit the CTE mismatch deformation. One of the layers may have a higher thermal conductivity than the other layers to increase heat transfer to the fluid and enhance thermal performance. One of the layers may be include copper, copper alloys (e.g. copper-tungsten alloys, copper-molybdenum alloys), aluminum, aluminum alloys, tungsten, tungsten alloys, silver, silver alloys, steel, aluminum nitride, ceramics comprising aluminum and/or copper, graphite, diamond, metal-metal composites, and/or metal-carbon composites depending on the desired thermal conductivity. The second layer may be a copper-tungsten, another copper alloy, or any suitable material such that the second layer may have a lower CTE than the first layer to decrease the CTE mismatch between the cold plate and underlying semiconductor chip(s). The layered metal cold plate may be formed by bonding. The layered metal cold plate may have more than two metals. The layered metal cold plate may be formed by additive manufacturing, powder sintering, casting, or forging. The layered metal cold plate may be machined in order to form fins or other heat transfer structures. The present disclosure may include an additively manufactured monolithic silicon carbide cold plate that contains topology optimized structures that enhance thermal performance and minimize pressure drop. The present disclosure may include a generative design methodology that develops an enhanced cooler fin structure by utilizing a genetic algorithm to compare and modify potential designs over numerous generations.

The present disclosure may include a 3U-sized CDU positioned on the backside of the rack, designed to achieve higher power density with a space-efficient flow loop architecture. While it may be appreciated that the coolant distribution unit may be of any size that is no larger than a total height of the server units connected to the CDU, the present disclosure may include a CDU for fewer server units on the backside of the rack, designed to achieve higher power density with a space-efficient flow loop architecture. The present disclosure may include a parallel flow loop connection of coolers integrated onto the major computing units, providing lower pressure drop and equal flow distribution to achieve uniform cooling performance for major computing components (CPUs and GPUs). The present disclosure may include a series flow loop connection of coolers integrated onto memories and SSDs, offering lower pressure drop and sufficient cooling performance for other computing components with hotter liquid. The present disclosure may include a modular-channel manifold on the primary loop, connecting facility pipes and brazed plate heat exchangers (BPHX) to ensure even heat transfer from the secondary loop to the primary loop. The present disclosure may include a modular-channel manifold on the secondary loop, ensuring even flow distribution with lower pressure drop from the dedicated modular CDU to one or more server units.

The present disclosure may include utilization of water exceeding 60°C on the server unit inlet side of the secondary loop, providing lower junction-to-coolant thermal resistance. By operating with high liquid temperatures, the present disclosure may enable effective cooling in varying ambient conditions and facilitate real-time monitoring and control. The present disclosure may include utilization of water, water-glycol, or any other biologically-friendly fluids exceeding 52°C on the outdoor chilling unit outlet side of the primary loop, allowing high primary loop liquid temperatures and enabling datacenter operation in locations with ambient temperatures exceeding 45°C. The present disclosure may include an outdoor heat reusing loop for surrounding facilities, with the potential to reduce TUE to near 1.0. The present disclosure may include underground pipes connected to a modular channel manifold attached to the rack, efficiently delivering heat from inside to outside without using separate space for ground pipes. The present disclosure may include a flow rate ranging from 0.1 LPM to 54 LPM per single CDU, allowing active control of the pump to achieve consistent junction temperature of computing units based on dynamic simulation results, machine learning model-based results, or real time thermal fluid parameters.

The present disclosure may include a separate filtering loop on the secondary loop, designed to reduce general pressure drop during cooling operation, enhancing pump efficiency. The present disclosure may include 3D-printed or molded connectors and fittings made of low thermal conductivity material, minimizing heat loss from the coolant to ambient, maintaining low ambient temperature inside the rack, and delivering energy to the outdoors for heat reuse. The present disclosure may include silicone-foam insulation covers for quick disconnects, minimizing heat loss from the coolant to ambient, maintaining low ambient temperature inside the rack, and delivering energy to the outdoors for heat reuse. The present disclosure may include insulation tubes, minimizing heat loss from the coolant to ambient, maintaining low ambient temperature inside the rack, and delivering energy to the outdoors for heat reuse. The present disclosure may include quick disconnects for the BPHX, coolers, and manifolds, facilitating easier maintenance and replacement of components without draining the system and preventing leakage.

The present disclosure may include a dynamic system model for datacenters, comprising a computational framework that determines optimal cooling unit (CDU) design and operational parameters, including flow rate and liquid temperature, based on dynamic thermal loads and ambient conditions, to achieve target junction temperatures and Total Power Usage Effectiveness (TUE). The present disclosure may include a system-level simulation model for comprehensive dynamic modeling that incorporates dynamic boundary conditions, including transient heat loads and ambient weather data, to accurately represent real-world physical phenomena in datacenter cooling systems. The present disclosure may include a system-level dynamic simulation model designed for a 3U modular cooling unit, with scalable implementation that can be adapted to various datacenter configurations. The present disclosure may include a dynamic simulation model featuring detailed specifications for detailed component integration of cooling system components, including heat exchangers, pumps, dry coolers, and sensors, to ensure accurate and thorough representation of the physical cooling system.

The present disclosure may include a method for improving thermal efficiency and energy consumption in a cooling system, using active control mechanisms for pumps and dry cooler fans to achieve a system TUE of 1.0074. The present disclosure may include a system incorporating active control strategies for pumps and fans to dynamically adjust and maintain target junction temperatures and optimize power consumption. The present disclosure may include a simulation model that includes multiple measuring points for temperature, pressure, and flow rate of each component, enabling real-time monitoring and dynamic adjustments to maintain optimal cooling performance. The present disclosure may include a dynamic simulation framework applicable beyond datacenters, adaptable for other applications with precise thermal management and dynamic system modeling, utilizing either the same simulation code or alternative programming tools.

The present disclosure may include enhanced reliability that includes a system for constructing complex cooling systems, providing reliable and accurate simulations for practical implementations. The present disclosure may include a user-friendly interface that includes a simulation framework, offering an accessible interface and a versatile coding environment for engineers and researchers to model and simulate datacenter cooling systems. The present disclosure may include a system-level analysis framework that integrates both thermal and hydraulic components, offering a complete view of cooling system performance under variable conditions. The present disclosure may include a method for modeling multi-domain systems, encompassing electrical, mechanical, and thermal domains, to address complex engineering challenges in cooling systems. The present disclosure may include a dynamic simulation model validated through sample results that demonstrate its capability to maintain target junction temperatures and optimize power consumption. The present disclosure may include a dynamic system model that facilitates the advancement of cooling technologies by evaluating the impact of novel components, such as coolers or thermal interface materials, on TUEs and junction temperatures, providing design guidance for their optimization.

In certain embodiments, the proposed cooling architecture allows for a heterogeneous mixture of modular coolant distribution units (CDUs) within the same rack. Unlike conventional systems that may standardize on a single CDU size or configuration, the disclosed approach enables the incorporation of multiple CDU modules, each differing in dimensions and capacity. For instance, a single rack might incorporate six 2U modular CDUs, four 3U modular CDUs, and two 9U modular CDUs. This heterogeneous arrangement provides designers with greater flexibility to tailor cooling resources to the specific thermal profiles of different server units or components. In scenarios where the rack includes both high-heat-dissipation computing nodes and lower-dissipation power supply units (PSUs), computing-intensive units can be connected to smaller modular CDUs to ensure more uniform and targeted flow distribution, while PSU units—generating comparatively less heat—may be grouped and served by a larger modular CDU. By systematically mixing and matching CDU sizes within a single rack, the cooling architecture can better adapt to the operational demands, improving overall energy efficiency and cooling precision.

The present disclosure enables simultaneous and dynamic control at the level of individual server units. Traditional cooling systems often rely on a uniform, static distribution of coolant, treating all units similarly regardless of their current load, thermal output, or operational state. Here, by contrast, the cooling infrastructure incorporates sensors, flow control devices, and intelligent algorithms that allow for independent adjustment of flow rates, coolant temperatures, and pressure setpoints for each server unit. This capability ensures that each unit can be precisely tuned to its instantaneous heat dissipation profile, whether it is a CPU-intensive compute node, a memory-heavy storage unit, or a low-power PSU.

Such unit-level dynamic control empowers the system to achieve heterogeneous heat dissipation profiles across the datacenter. Rather than enforcing a one-size-fits-all cooling strategy, the system can transiently respond to localized conditions. For example, one server undergoing a brief computational spike may receive a short-term increase in coolant flow, while another server running at nominal load remains at a baseline flow level. This granular approach reduces energy waste, maintains consistent chip temperatures, and extends the lifetime of hardware components by ensuring they remain within optimal thermal ranges.

The present disclosure also emphasizes the optimization of the entire physical cooling infrastructure that supports the datacenter environment. This optimization process can address key components such as manifolds, brazed plate heat exchangers (BPHXs), pumps, and dry coolers to ensure balanced performance across the system. For manifolds, considerations include the number of manifold splits, the internal geometry that governs pressure drops, and the configuration that ensures uniform flow distribution. By strategically designing or selecting manifold layouts, it is possible to minimize flow resistance and improve the responsiveness of the system to dynamic load changes. In the case of BPHXs, physical parameters such as size, heat exchange capacity, and pressure drop characteristics come into play. Optimizing these factors ensures efficient transfer of thermal energy, minimal energy losses, and reduced fluid resistance. Similarly, pumps must be chosen or configured based on size, speed, and volumetric flow rate capabilities that match the dynamic cooling demands of the system. Oversized pumps may lead to large power consumption, while undersized pumps can restrict performance under peak loads. Dry coolers use careful consideration of fan power consumption, pressure drops, overall heat capacity, and physical footprint. By holistically optimizing these elements—manifolds, BPHXs, pumps, and dry coolers—the system can achieve superior overall efficiency, improved reliability, and enhanced scalability, supporting both current and future datacenter infrastructure demands.

While the physical optimization of the cooling hardware is essential, it must be complemented by sophisticated control strategies that optimize flow parameters in real-time. Such strategies ensure consistent chip temperatures and minimize total-power usage effectiveness (TUE) under fluctuating ambient conditions and variable data loads. For example, as server workloads shift throughout the day or week, the system can dynamically adjust flow rates, coolant temperatures, and pump pressures to maintain stable thermal conditions without resorting to overcooling or undercooling any specific component.

Achieving these goals may be facilitated by advanced communication protocols and user-friendly interfaces. Operators can interact with software dashboards that visualize the current cooling topology, highlight areas of inefficiency, and provide recommended adjustments. Automated controllers can implement these adjustments in near-real time, guided by pre-established optimization algorithms or machine learning models (FIGS. 3A & 3B). Through this integrated approach—combining physical infrastructure tuning with dynamic parameter adjustments—the system consistently maintains high performance and resource efficiency. The result is a datacenter environment that can intelligently anticipate and respond to changing operational demands, delivering optimal cooling outcomes through a combination of hardware and software orchestrations.

An additional layer of innovation lies in the integration of machine learning (ML) and artificial intelligence (AI) to guide the design, configuration, and continuous optimization of the cooling architecture. The system can leverage historical data, predictive analytics, and intelligent algorithms to generate recommendations for various architectural parameters. For instance, the AI system could suggest how many server units should connect to a single modular CDU or determine the most effective combination of heterogeneous modular CDU architecture within a given rack based on current thermal loads, past performance metrics, and predicted future usage trends.

Beyond rack-level optimizations, AI can also advise on how best to group multiple racks together and connect them to a single dry cooler, as well as determine the optimal flow rates for each server unit. The system may generate short-term adjustments based on real-time data or longer-term forecasts spanning daily, weekly, monthly, or even annual scales. By continuously analyzing historical operational data and comparing predicted versus actual performance outcomes, the AI-based system tunes the cooling parameters over time. In doing so, it ensures that the datacenter’s cooling strategy remains aligned with evolving computational demands, seasonal variations in climate, and energy consumption goals, ultimately maintaining a highly efficient and sustainable thermal management ecosystem.

The optimization platform enables optimization of physical sizing, distribution, and capacity of the dry cooler infrastructure which connects to the racks. This includes optimization of the piping connecting the rack or racks to the dry cooler or dry coolers. This enables the determination of optimal flow layout, performance, and minimal system TUE.

FIG. 6 is a block diagram 600 of internal and external components of IT systems depicted in FIG. 1 in accordance with an illustrative embodiment. It should be appreciated that FIG. 6 provides only an illustration of one implementation and does not imply any limitations with regard to the environments in which different embodiments may be implemented. Many modifications to the depicted environments may be made based on design and implementation details.

Computer 102 (FIG. 1) and server computer 114 (FIG. 1) may include respective sets of internal components 800A,B and external components 900A,B illustrated in FIG. 6. Each of the sets of internal components 800 include one or more processors 820, one or more computer-readable RAMs 822 and one or more computer-readable ROMs 824 on one or more buses 826, one or more operating systems 828, and one or more computer-readable tangible storage devices 830.

Processor 820 is implemented in hardware, firmware, or a combination of hardware and software. Processor 820 is a central processing unit (CPU), a graphics processing unit (GPU), an accelerated processing unit (APU), a microprocessor, a microcontroller, a digital signal processor (DSP), a field-programmable gate array (FPGA), an application-specific integrated circuit (ASIC), or another type of processing component. In some implementations, processor 820 includes one or more processors capable of being programmed to perform a function. The one or more buses 826 include a component that permits communication among the internal components 800A,B.

The one or more operating systems 828, the software program 108 (FIG. 1) and the Architecture Optimization Program 116 (FIG. 1) on server computer 114 (FIG. 1) are stored on one or more of the respective computer-readable tangible storage devices 830 for execution by one or more of the respective processors 820 via one or more of the respective RAMs 822 (which typically include cache memory). In the embodiment illustrated in FIG. 6, each of the computer-readable tangible storage devices 830 is a magnetic disk storage device of an internal hard drive. Alternatively, each of the computer-readable tangible storage devices 830 is a semiconductor storage device such as ROM 824, EPROM, flash memory, an optical disk, a magneto-optic disk, a solid-state disk, a compact disc (CD), a digital versatile disc (DVD), a floppy disk, a cartridge, a magnetic tape, and/or another type of non-transitory computer-readable tangible storage device that can store a computer program and digital information.

Each set of internal components 800A,B also includes a R/W drive or interface 832 to read from and write to one or more portable computer-readable tangible storage devices 936 such as a CD-ROM, DVD, memory stick, magnetic tape, magnetic disk, optical disk or semiconductor storage device. A software program, such as the software program 108 (FIG. 1) and the Architecture Optimization Program 116 (FIG. 1) can be stored on one or more of the respective portable computer-readable tangible storage devices 936, read via the respective R/W drive or interface 832 and loaded into the respective computer-readable tangible storage devices 830.

Each set of internal components 800A,B also includes network adapters or interfaces 836 such as a TCP/IP adapter cards; wireless Wi-Fi interface cards; or 3G, 4G, or 5G wireless interface cards or other wired or wireless communication links. The software program 108 (FIG. 1) and the Architecture Optimization Program 116 (FIG. 1) on the server computer 114 (FIG. 1) can be downloaded to the computer 102 (FIG. 1) and server computer 114 from an external computer via a network (for example, the Internet, a local area network or other, wide area network) and respective network adapters or interfaces 836. From the network adapters or interfaces 836, the software program 108 and the Architecture Optimization Program 116 on the server computer 114 are loaded into the respective computer-readable tangible storage devices 830. The network may comprise copper wires, optical fibers, wireless transmission, routers, firewalls, switches, gateway computers and/or edge servers.

Each of the sets of external components 900A,B can include a computer display monitor 920, a keyboard 930, and a computer mouse 934. External components 900A,B can also include touch screens, virtual keyboards, touch pads, pointing devices, and other human interface devices. Each of the sets of internal components 800A,B also includes device drivers 840 to interface to computer display monitor 920, keyboard 930 and computer mouse 934. The device drivers 840, R/W drive or interface 832 and network adapter or interface 836 comprise hardware and software (stored in the computer-readable tangible storage devices 830 and/or ROM 824).

Some embodiments may relate to a system, a method, and/or a computer program product at any possible technical detail level of integration. The computer program product may include a computer-readable non-transitory storage medium (or media) having computer readable program instructions thereon for causing a processor to carry out operations.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program code/instructions for carrying out operations may be assembler instructions, instruction-set-architecture (ISA) instructions, machine instructions, machine dependent instructions, microcode, firmware instructions, state-setting data, configuration data for integrated circuitry, or either source code or object code written in any combination of one or more programming languages, including an object oriented programming language such as Smalltalk, C++, or the like, and procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects or operations.

These computer readable program instructions may be provided to a processor of a general-purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus, or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer readable media according to various embodiments. In this regard, cache block in the flowchart or block diagrams may represent a module, segment, or portion of instructions, which comprises one or more executable instructions for implementing the specified logical function(s). The method, computer system, and computer program product may include additional blocks, fewer blocks, different blocks, or differently arranged blocks than those depicted in the Figures. In some alternative implementations, the functions noted in the blocks may occur out of the order noted in the Figures. For example, two blocks shown in succession may, in fact, be executed concurrently or substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

It will be apparent that systems and/or methods, described herein, may be implemented in different forms of hardware, firmware, or a combination of hardware and software. The actual specialized control hardware or software code used to implement these systems and/or methods is not limiting of the implementations. Thus, the operation and behavior of the systems and/or methods were described herein without reference to specific software code—it being understood that software and hardware may be designed to implement the systems and/or methods based on the description herein.

No element, act, or instruction used herein should be construed as critical or essential unless explicitly described as such. Also, as used herein, the articles “a” and “an” are intended to include one or more items and may be used interchangeably with “one or more.” Furthermore, as used herein, the term “set” is intended to include one or more items (e.g., related items, unrelated items, a combination of related and unrelated items, etc.), and may be used interchangeably with “one or more.” Where only one item is intended, the term “one” or similar language is used. Also, as used herein, the terms “has,” “have,” “having,” or the like are intended to be open-ended terms. Further, the phrase “based on” is intended to mean “based, at least in part, on” unless explicitly stated otherwise.

The descriptions of the various aspects and embodiments have been presented for purposes of illustration but are not intended to be exhaustive or limited to the embodiments disclosed. Even though combinations of features are recited in the claims and/or disclosed in the specification, these combinations are not intended to limit the disclosure of possible implementations. In fact, many of these features may be combined in ways not specifically recited in the claims and/or disclosed in the specification. Although each dependent claim listed below may directly depend on only one claim, the disclosure of possible implementations includes each dependent claim in combination with every other claim in the claim set. Many modifications and variations will be apparent to those of ordinary skill in the art without departing from the scope of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method of optimizing a liquid cooling architecture for a datacenter, executable by a processor, comprising:
receiving operational parameters corresponding to a datacenter and a plurality of server units to be mounted in a rack within the datacenter;
determining groups of one or more server units from among the plurality of server units based on the operational parameters;
causing the server units to be mounted in the rack based on the determined groups; and
causing a group of server units from among the determined groups to be connected to a coolant distribution unit, wherein each server computer in the group of server units is connected to the coolant distribution unit in parallel.

2. The method of claim 1, wherein each group of server units includes one or more server units mounted within the rack having a size of one rack unit (1U), two rack units (2U), three rack units (3U), or more; and
wherein the coolant distribution unit has a size no larger than a total height of the connected server units and is caused to be mounted to a rear side of the rack.

3. The method of claim 1, wherein the operational parameters comprise transient heat load information for the server units, cooling solution connectivity configuration information for the server units, weather or climate data corresponding to a location of the datacenter, and ambient temperature data within the datacenter.

4. The method of claim 1, wherein determining the groups of the one or more server units comprises:
iteratively simulating candidate datacenter cooling architectures based on the operational parameters;
determining an optimal configuration for the server units based on identifying a candidate datacenter cooling architecture having a lowest total power usage effectiveness from among the iteratively simulated candidate datacenter cooling architectures; and
grouping the server units within the rack based on the determined optimal configuration.

5. The method of claim 4, wherein each datacenter cooling architecture of the candidate datacenter cooling architectures comprises:
a primary cooling loop comprising a cooling unit, one or more first pipes or tubes, and one or more first pumps;
a secondary cooling loop comprising one or more coolers, the coolant distribution units, one or more second pipes or tubes, and one or more second pumps; and
one or more heat exchangers coupled to the primary cooling loop and the secondary cooling loop.

6. The method of claim 5, wherein determining the optimal configuration for the server units comprises iteratively determining a shape of the coolers based on minimizing the total power usage effectiveness.

7. The method of claim 6, wherein the total power usage effectiveness is minimized through a weighted objective function based on balancing a heat transfer efficiency of the datacenter cooling architecture, a pressure drop minimization of the datacenter cooling architecture, and manufacturing constraints.

8. A system for optimizing a liquid cooling architecture for a datacenter, comprising:
one or more non-transitory computer-readable storage media configured to store computer program code; and
one or more processors configured to access the computer program code and operate as instructed by the computer program code, the computer program code including:
receiving code configured to cause the one or more processors to receive operational parameters corresponding to a datacenter and a plurality of server units to be mounted in a rack within the datacenter;
determining code configured to cause the one or more processors to determine groups of one or more server units from among the plurality of server units based on the operational parameters;
mounting code configured to cause the one or more processors to cause the server units to be mounted in the rack based on the determined groups; and
connecting code configured to cause the one or more processors to cause a group of server units from among the determined groups to be connected to a coolant distribution unit, wherein each server computer in the group of server units is connected to the coolant distribution unit in parallel.

9. The system of claim 8, wherein each group of server IT systems includes one or more server units mounted within the rack having a size of one rack unit (1U), two rack units (2U), three rack units (3U), or more IT systems; and
wherein the coolant distribution unit has a size no larger than a total height of the connected server units is caused to be mounted to a rear side of the rack.

10. The system of claim 8, wherein the operational parameters comprise transient heat load information for the server units, cooling solution connectivity configuration information for the server units, weather or climate data corresponding to a location of the datacenter, and ambient temperature data within the datacenter.

11. The system of claim 8, wherein the determining code stored on the one or more non-transitory computer-readable storage media further comprises:
simulating code configured to cause the one or more processors to iteratively simulate candidate datacenter cooling architectures based on the operational parameters;
second determining code configured to cause the one or more processors to determine an optimal configuration for the server units based on identifying a candidate datacenter cooling architecture having a lowest total power usage effectiveness from among the iteratively simulated candidate datacenter cooling architectures; and
grouping code configured to cause the one or more processors to group the server units within the rack based on the determined optimal configuration.

12. The system of claim 11, wherein a datacenter cooling architecture corresponding to the candidate datacenter cooling architectures comprises:
a primary cooling loop comprising a cooling unit, one or more first pipes or tubes, and one or more first pumps;
a secondary cooling loop comprising one or more coolers, the coolant distribution units, one or more second pipes or tubes, and one or more second pumps; and
one or more heat exchangers coupled to the primary cooling loop and the secondary cooling loop.

13. The system of claim 12, wherein the second determining code further comprises:
third determining code configured to cause the one or more processors to determine a shape of the coolers based on minimizing the total power usage effectiveness.

14. The system of claim 13, wherein the total power usage effectiveness is minimized through a weighted objective function based on balancing a heat transfer efficiency of the datacenter cooling architecture, a pressure drop minimization of the datacenter cooling architecture, and manufacturing constraints.

15. A computer program product for optimizing a liquid cooling architecture for a datacenter, comprising:
one or more non-transitory computer-readable storage devices; and
program instructions stored on at least one of the one or more non-transitory computer-readable storage devices, the program instructions being executable by one or more processors and configured to cause the one or more processors to perform the method of claim 1.

16. A liquid cooling system for a datacenter comprising:
a rack;
one or more groups of one or more server units mounted within the rack having a size of one rack unit (1U), two rack units (2U), three rack units (3U), or more
a primary cooling loop comprising a cooling unit, one or more first pipes or tubes, and one or more first pumps;
a secondary cooling loop for each of the one or more groups of the one or more server units, each secondary cooling loop comprising one or more coolers in contact with one or more components of the server units, a coolant distribution unit mounted to a rear side of the rack and connected in parallel with each 1U server computer in the group, one or more second pipes or tubes, and one or more second pumps mounted to the rear side of the rack; and
one or more heat exchangers mounted to the rear side of the rack and operatively coupled to the primary cooling loop and the secondary cooling loop.

17. The liquid cooling system of claim 14, wherein the cooling unit comprises a dry cooler located outdoors in relation to the datacenter.

18. The liquid cooling system of claim 14, wherein each cooler comprises a bimetallic microstructured cooler comprising a copper-tungsten base plate bonded to a copper top layer.

19. The liquid cooling system of claim 14, wherein the heat exchanger comprises a brazed plate heat exchanger.

20. The liquid cooling system of claim 14, wherein the coolant distribution unit has a size no larger than a total height of the group of the server units to which the coolant distribution unit is connected.
